(19) United States
(12) Patent Application Publication
(10) Pub. No.: US 2014/0241848 A1
(43) Pub. Date: Aug. 28, 2014

(54) ELECTRIC SWITCHABLE MAGNET SLITVALVE

(71) Applicant: VARIAN SEMICONDUCTOR EQUIPMENT ASSOCIATES, INC., Gloucester, MA (US)

(72) Inventors: Robert Brent Vopat, Austin, TX (US); Jeffrey Blahnik, Leander, TX (US); Christopher Grant, Dripping Springs, TX (US); William T. Weaver, Austin, TX (US)

(73) Assignee: VARIAN SEMICONDUCTOR EQUIPMENT ASSOCIATES, INC., Gloucester, MA (US)

(21) Appl. No.: 13/775,581

(22) Filed: Feb. 25, 2013

(51) Int. Cl. E06B 7/16; H01L 21/677

(52) U.S. Cl. CPC E06B 7/16; H01L 21/677
USPC 414/805; 49/478.1

(57) ABSTRACT

A slitvalve that uses magnetic energy to move a door in a direction normal to the plane of the wall is disclosed. An electrically switchable magnet is used to draw the door toward the wall to seal an aperture in the wall. Compressed Dry Air or other mechanisms may be employed to move the door between a first open position and a second closed position. A method of passing a workpiece between two different environments utilizing this magnetic slitvalve is also disclosed.

### TECHNICAL FIELD

Embodiments of the present invention relate to methods and apparatus for providing an automated gas tight seal of an opening, more specifically, an electric switchable magnet slitvalve for sealing chambers in a semiconductor tool.

### BACKGROUND

Semiconductor workpieces are processed within process chambers. Workpieces are typically moved from one chamber to another by automated means. Often, each chamber must be environmentally isolated from other chambers. Consequently, the workpieces are typically moved between chambers by the use of load locks. These load locks serve to isolate a particular chamber from its outside environment. Additionally, a difference in pressure may exist on either side of the load lock. For example, near vacuum conditions may exist within the chamber, while the outside environment may be at standard atmospheric pressure. Thus, the load must also seal the chamber against these differences in pressure.

Load locks typically include a slitvalve, which includes a wall with an aperture included therein, and an associated movable door assembly. The movable door assembly may include a first portion, referred to as the door, which is at least as large as the aperture, and a movable shaft. In a first position, the door is moved away, such as vertically downward, so that the aperture is open and workpieces can be moved therethrough. In a second position, the door is disposed to cover the aperture, thereby separating the regions on opposite sides of the wall from each other.

The door is typically driven and held in place by the use of compressed dry air (CDA). For example, an air cylinder may serve to move the door in a first direction, where the first direction is defined as a direction parallel to the plane of the wall, between the first and second positions. To seal, the door must also be moved in a second direction, normal to the plane of the wall. In some embodiments, the door is biased against the wall through the use of air cylinders. In other embodiments, the door expands in the second direction, which serves to seal the door against the aperture.

These methods require an excessive amount of CDA. Also, the movement of the door in the second direction often results in bending or excessive tension of the shaft, which reduces the effectiveness and reliability of the load lock. Furthermore, the pressure applied by the door against the wall is uneven, typically necessitating a heavier, thicker door.

Therefore, it would be beneficial if there were a slitvalve that required less CDA and was more reliable.

### SUMMARY

Systems and method comprising a slitvalve using magnetic energy are disclosed. In a first embodiment, the slitvalve comprises a wall defining an aperture; an electrically switchable magnet disposed in a location of the wall; and a movable door assembly, comprising a door having magnetically attracted material, disposed so as correspond to the location of the electrically switchable magnet when the door is in a closed position; and an actuator to move the door in a first direction parallel to a plane of the wall between the closed position and an open position.

In a second embodiment, the slitvalve comprises a wall defining an aperture; a movable door; a first actuator to move the door in a first direction, parallel to a plane of the wall; and an electrically switchable magnet to move the door in a second direction, normal to the plane of the wall.

In another embodiment, a method of passing a workpiece between two environments is disclosed. The method of passing a workpiece from a first environment to a second environment, separated from the first environment by a wall having an aperture therethrough, where the aperture is sealed using a movable door, the method comprises providing a magnetically attracted material on the door; deactivating an electrically switchable magnet disposed in the wall, thereby releasing the magnetically attracted material from the wall; using a force to maintain separation between the wall and the door; using an actuator to move the door from a second position to a first position; passing the workpiece through the aperture when the door is in the first position; using the actuator to move the door to the second position; and activating the electrically switchable magnet to attract the magnetically attracted material in the door, thereby sealing the door to the wall.

### BRIEF DESCRIPTION OF THE FIGURES

For a better understanding of the present disclosure, reference is made to the accompanying drawings, which are incorporated herein by reference and in which:

FIG. 1A is an isometric view of a slitvalve according to one embodiment in the first, open position;

FIG. 1B is an isometric view of the slitvalve of FIG. 1A in the second closed position;

FIG. 2 represents a rear view of the wall of the slitvalve of FIG. 1A;

FIG. 3 represents a front view of the door of the slitvalve of FIG. 1A;

FIG. 4 represents a second embodiment of the wall of the slitvalve;

FIG. 5 represents the magnetic fields associated with a first configuration of magnets shown in FIG. 4;

FIG. 6 represents the magnetic fields associated with a second configuration of magnets; and

FIG. 7 is a flowchart illustrating the operation of a slitvalve according to one embodiment.

### DETAILED DESCRIPTION

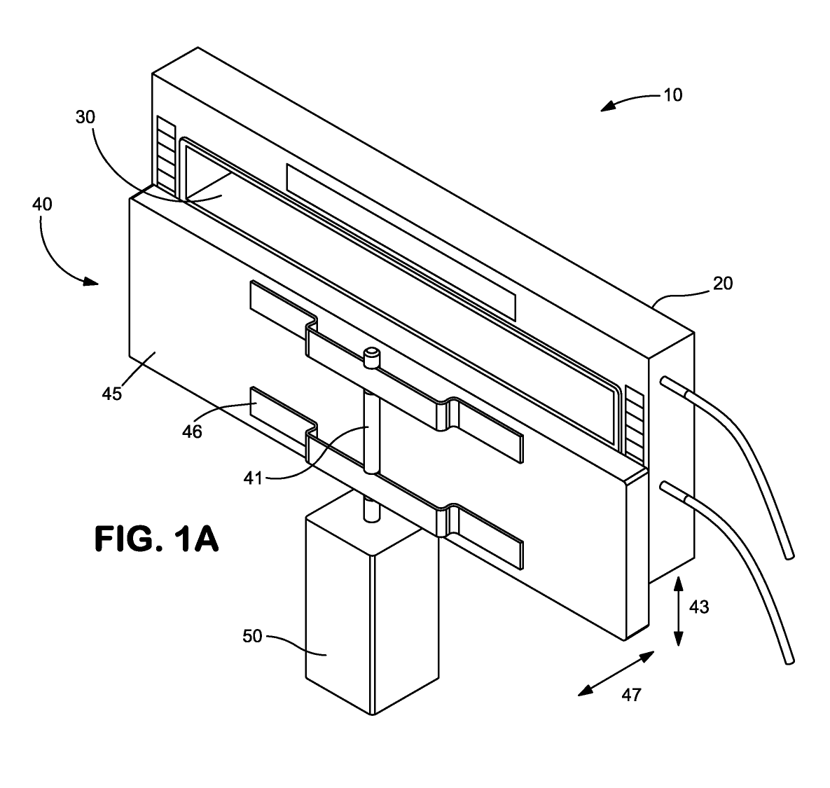

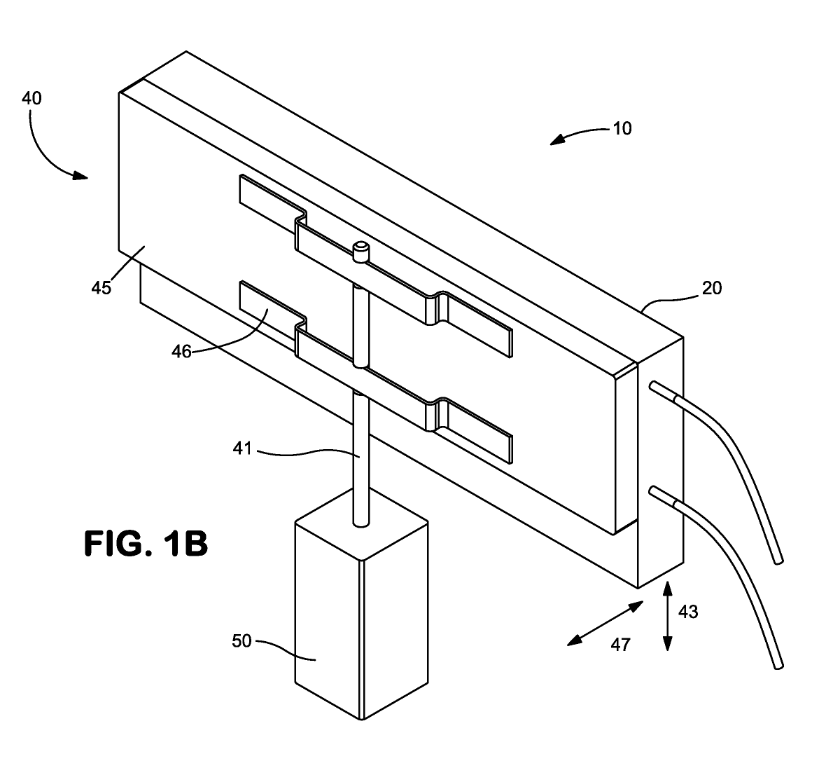

FIG. 1 is an isometric view of the slitvalve 10 in the first, or open position, in accordance with one embodiment. The slitvalve 10 includes a wall 20 with an aperture 30. The wall 20 may be constructed of aluminum or any other suitable material. The slitvalve 10 also includes a movable door assembly 40, which has a movable shaft 41 attached to a door 45. The door 45 may also be constructed from aluminum or any other suitable material. The movable shaft 41 may be in communication with an actuator 50, such as an air cylinder or other pneumatic or mechanical device. The actuator 50 is used to move the shaft 41, and consequently the door 45, in a first direction, indicated by arrows 43, where the first direction is parallel to the plane of the wall 20. The door 45 may be attached to the movable shaft 41 using one or more flexure plates 46. These flexure plates 46 allow for some movement in a second direction, normal to the plane of the wall 20, indicated by arrows 47. Although flexure plates 46 are described below, any suitable mechanism that allows movement along second direction 47 may be used. For example, linear bearings may be employed to achieve this movement. Additionally, other mechanisms, such as shaft and ball slides, may also be employed.

CDA may be used to actuate the movable shaft in the first direction 43, thereby moving the door 45 from a first open position, shown in FIG. 1A, to a second closed position, shown in FIG. 1B.

Unlike prior art devices, the slitvalve 10 uses magnetic force to move the door 45 in the second direction 47 and to hold the door 45 against the wall 20. One or more electrically switchable magnets may be used to create the desired magnetic field. An electrically switchable magnet is defined as a magnet whose magnet field can be modified through the application of electrical current. In one embodiment, an electrically switchable magnet may comprise an electromagnet, where a wire is wrapped around a ferrite material. Application of current in one direction polarizes the ferrite material in one orientation, while application of current in the opposite direction polarizes the ferrite material in the opposite direction. The lack of electrical current eliminates the magnetic field. In a second embodiment, the electrical switchable magnet may be an electrical switchable permanent magnet. An electrical switchable permanent magnet has two states; an active state where a magnetic field is present and a second passive state where no magnetic field exists. This can be achieved in a number of ways. In one embodiment, a permanent magnet is arranged with an electromagnet, which either accentuates the inherent magnetic field of the permanent magnet, or short circuits it. In a second embodiment, a permanent magnet is arranged with a second rotatable permanent magnet, which either accentuates the inherent magnetic field or short circuits it. In a third embodiment, a permanent magnet is arranged with a second permanent magnet, which is wound with an electrical coil. The polarity of the second permanent magnet can be reversed by a brief application of voltage, thereby creating two states where the magnetic field is either accentuated or short circuited. One additional quality of electrical switchable permanent magnets is their ability to maintain state in the absence of electrical current. These electrical switchable permanent magnets may be made from, for example, alnico or rare earth metals, such as neodymium, and samarium-cobalt. In other words, electrical current is only needed to set the magnet in one of its two states. After that, the electrical switchable permanent magnet will maintain that state until an electrical current is used to change to the other state.

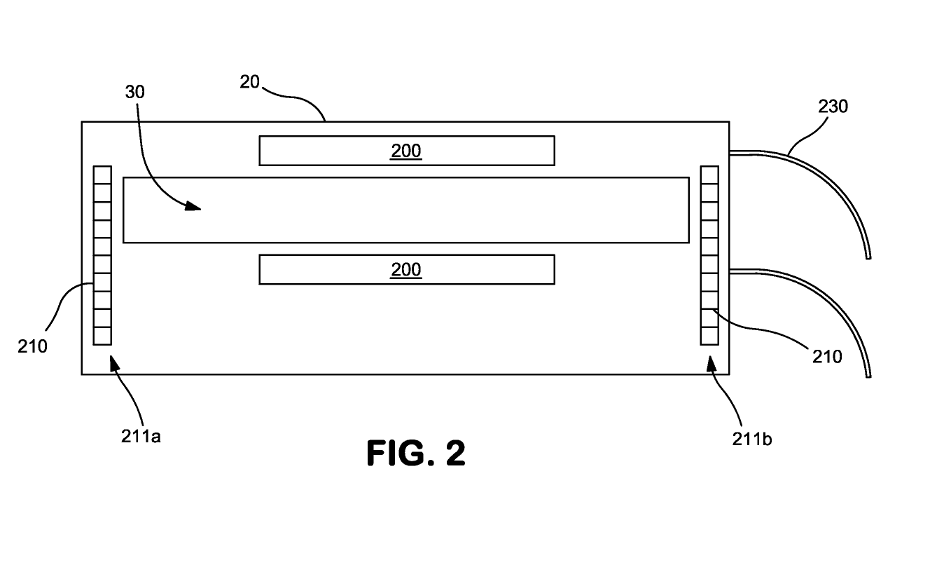

FIG. 2 shows a wall 20, having a plurality of electrically switchable magnets 200 disposed thereon. These electrically switchable magnets 200 may be embedded in the wall 20 in some embodiments. In some embodiments, these electrically switchable magnets 200 are disposed around at least a portion of the perimeter of the aperture 30. For example, the electrically switchable magnets 200 may be disposed along the top and bottom edges of the aperture 30. In another embodiment, the electrically switchable magnets 200 may be disposed along each edge of the aperture 30. Other configurations of the electrically switchable magnets 200 are also within the scope of the disclosure. These electrically switchable magnets 200 are actuated by a power source (not shown), which is electrically coupled to the magnets 200 using conduits 230.

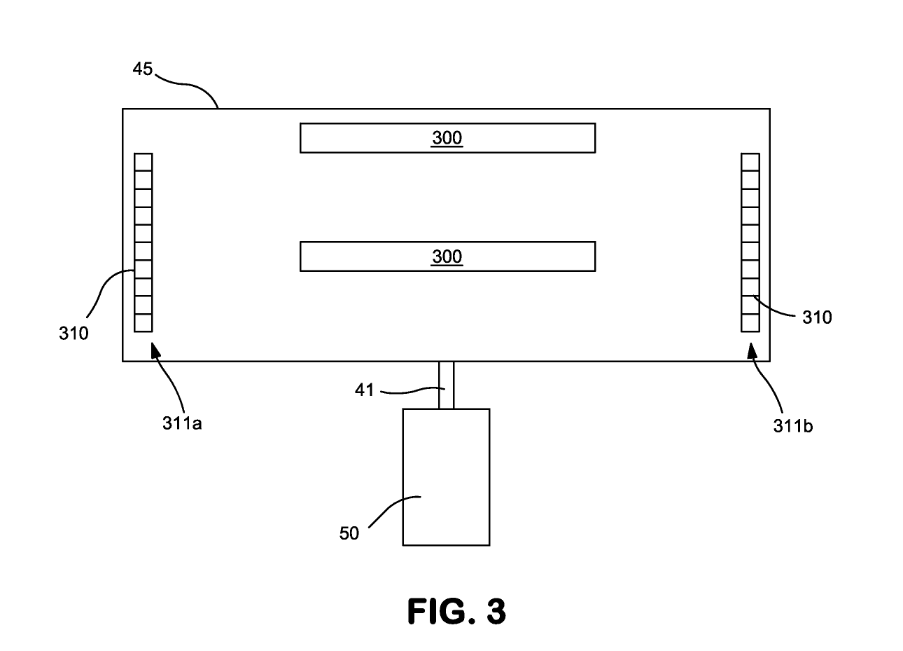

As shown in FIG. 3, magnetically attracted material 300, such as steel or iron, is disposed on or in the door 45. The position of the magnetically attracted material 300 is selected to correspond to the locations of the electrically switchable magnets 200 when the door 45 is in the second closed position. In other embodiments, the magnetically attracted material 300 is disposed on the wall 20, while the electrically switchable magnets 200 are disposed on the door 45.

In operation, the electrically switchable magnets 200 are first set to their non-magnetic state. After this, since the door 45 is no longer being held in place, the door 45 can be moved in the first direction, by actuation of the air cylinder 50 through the use of CDA. When returning the door 45 to the second closed position, the air cylinder 50 is actuated so as to extend the shaft 41 to move the door 45 in the first direction 43. When the door 45 has reached its second closed position, the electrically switchable magnets 200 are set to their magnetically energized state. This action draws the magnetically attracted material 300, and consequently the door 45, toward the wall 20, thereby sealing it in place. The magnitude of the magnetic field exerted by the electrically switchable magnets 200 can be selected according to the design criteria of the application. For some embodiments, the magnetic field generated by each electrically switchable magnet 200 may be hundreds of pounds, such as greater than 500 pounds each. To improve the quality of the seal between the door 45 and the wall 20, an o-ring seal (not shown) may be placed on the wall 20, the door 45 or on both the wall 20 and the door 45.

As stated above, flexure plates 46 attach the door 45 to the movable shaft 41. These plates 46 may have a spring like quality, allowing them to stretch and compress. The flexure plates 46 may be constructed of any suitable material, such as metal or a polymer. When the door 45 is being drawn to the wall 20 due to the magnetic field, flexure plates 46 stretch, allowing the door 45 to move in the second direction 47 toward the wall 20. When the electrically switchable magnets 200 are set to the passive state, the flexure plates 46 may compress back to their natural shape, thereby drawing the door 45 away from the wall 20. The ability of the flexure plates 46 to stretch minimizes the moment force that is exerted on the movable shaft 41, thus improving its reliability and useable life. As stated above, other mechanisms may be used to allow movement along the second direction 47.

In some embodiments, a force may be used to maintain separation between the door 45 and the wall 20, especially while the door 45 is traveling between its first open position and second closed position. In one embodiment, as shown in FIG. 2, magnets 210, disposed in or on the wall 20, are arranged in linear arrays 211a, 211b corresponding to the door's direction of travel 43. These magnets 210 may be permanent magnets, such as neodymium magnets. These magnets 210 may be arranged such that the same pole (north or south) of each magnet faces the outer surface of the wall 20. In one embodiment, two linear arrays of magnets 211a, 211b are employed, where one linear array of magnets 211a or 211b is disposed on each side of the aperture 30.

Similar sets of linear arrays 311a, 311b of magnets 310 may be disposed on the door 45, as shown in FIG. 3. These magnets 310 may also be permanent magnets, and are arranged such that the same pole is exposed on the surface of the door 45. These magnets 310 may be arranged in opposed pole alignment with the magnets 210. Each linear array 311a, 311b is located on the door 45 so as to spatially align with a corresponding linear array 211a, 211b on the wall 20. In this embodiment, two linear arrays 311 are shown, one on either side of the door 45. In this way, the magnets 210 of the wall 20 and the magnets 310 of the door 45 repel each other and will maintain separation between the door 45 and the wall 20, when the electrically switchable magnets 200 are in their passive state. By configuring these magnets 210, 310 as linear arrays 211, 311, the repulsion force is maintained through the full travel of the door 45, as it moves from its open position to its closed position. The use of linear arrays also serves to minimize the number of magnets required to create the desired repulsion force, and serves as a separation mechanism.

In this embodiment, the force of the electrically switchable magnets 200 must be sufficient to overcome the repulsion force between magnets 210 and 310, and hold the door 45 to the wall 20 with sufficient force. For example, if the desired force of the door 45 against the wall 20 is 400 pounds, and the repulsion force of the magnets 210 and 310 is 200 pounds, the electrically switchable magnets 200 should exert a force of at least 600 pounds.

In another embodiment, magnets 210, 310 may be electrically switchable magnets, such as electromagnets. In this embodiment, these electromagnets 210, 310 are disabled when the electrically switchable magnets 200 are set to their active state. These electromagnets 210, 310 would then be energized prior to actuating the air cylinder 50 to insure separation between the door 45 and the wall 20 when the door 45 is moving.

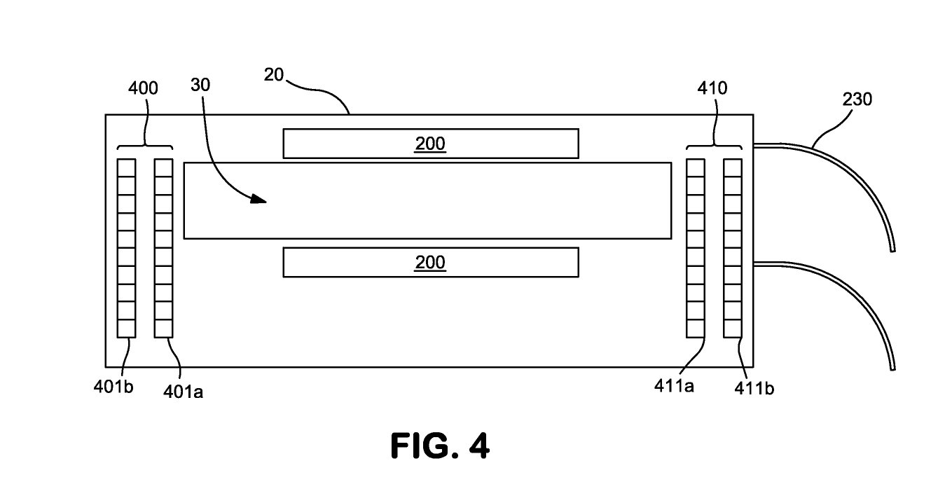

In another embodiment, shown in FIG. 4, the magnets on wall 20 are arranged in a first set 400 on one side of the aperture 30, where this first set has two linear arrays of magnets: an inner linear array 401a, closer to the aperture 30 and a outer array 401b, disposed further from the aperture 30. A second set of magnets 410, also having an inner linear array 411a and an outer array 411b, is disposed on the other side of the aperture 30. All of these linear arrays 401a, 401b, 411a, 411b are configured with the same pole facing outward. In this embodiment, the door 45 has two linear arrays 311a, 311b, as shown in FIG. 3.

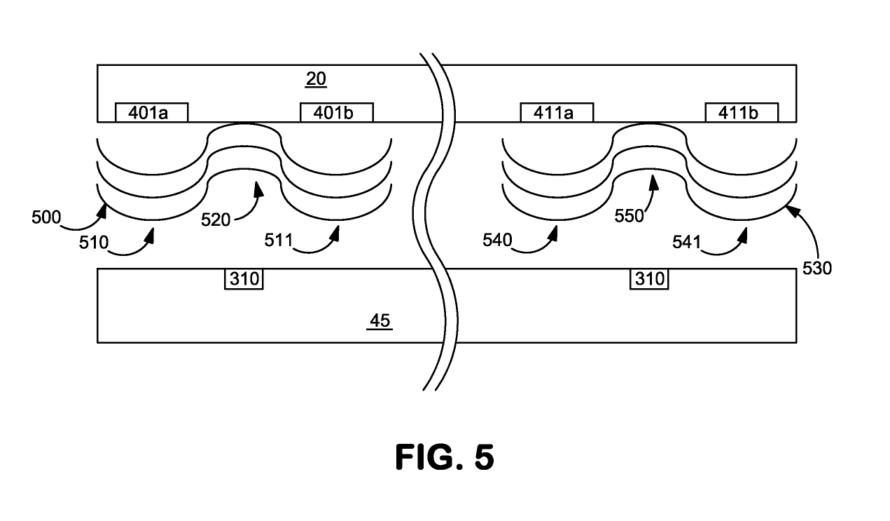

FIG. 5 shows an expanded top view of the interaction between the magnets disposed on the wall 20 and the door 45 in one configuration. This configuration of linear arrays 401a, 401b creates a magnetic field 500 with two peaks 510, 511 and a trough 520 therebetween, as shown in FIG. 5. The linear array 311b (see FIG. 3) of magnets 310 on the door 45 are disposed so as to be located in this trough 520. The magnetic peaks 510, 511 on either side of magnets 310 serve to align and hold the magnets 310 in place. A similar magnetic field 530 exists between linear arrays 411a, 411b, such that two magnetic peaks 540, 541 and a trough 550 therebetween are created. The linear array 311a (see FIG. 3) of magnets 310 on the opposite edge of the door 45 is disposed in this trough 550. This creates an alignment mechanism, such that the door 45 moves along the desired path in the direction 43 and cannot move from side to side. Thus, this configuration of magnets provides a separation mechanism and an alignment mechanism.

FIGS. 4 and 5 illustrate two sets 400, 410 of magnets, each having two linear arrays 401a, 401b, 411a, 411b, respectively, on the wall 20 and two sets each with one linear array 310a, 311b on the door 45. However, other embodiments are possible. For example, multiple linear arrays of magnets may be disposed on the door 45 with a single linear array on the wall 20.

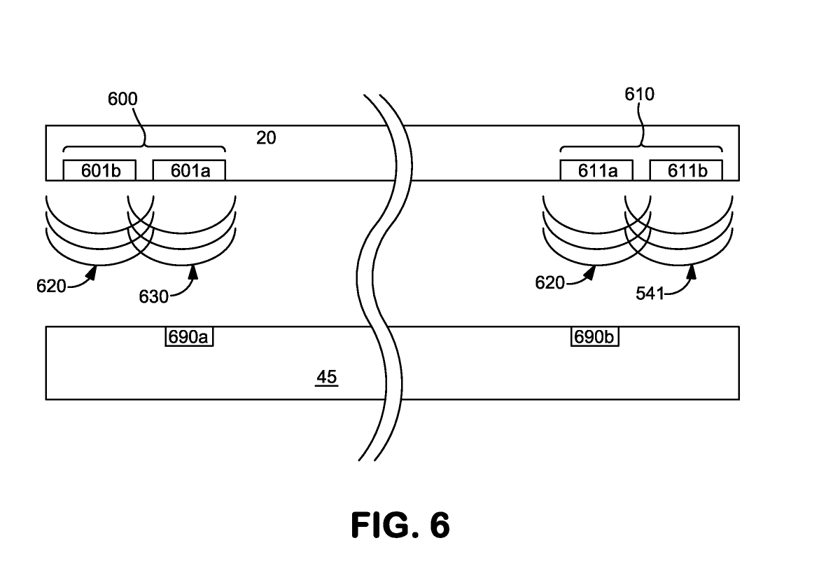

FIG. 6 is a top view of another arrangement of which may be used as an alignment mechanism. Similar to FIG. 4, two sets 600, 610 of magnets, respectively, each having an inner linear array 601a, 611a and an outer linear array 601b, 611b, are disposed on the wall 20. Similarly, two linear arrays 690a, 690b of magnets, one on each side, are disposed on the door 45, as in FIG. 3. However, the spatial relationship between the opposing magnets is altered. In this embodiment, the linear arrays 690a, 690b on the door are aligned directly with the inner pair of linear arrays 601a, 611a on the wall 20. The outer linear arrays 601b, 611b tend to repel each of the linear arrays of magnets 690a, 690b inward. Since these forces are counter to one another, the door 45 remains aligned. The configuration of FIG. 6 can be altered so that the magnets 690a, 690b are aligned with the outer linear arrays 601b, 611b. In this embodiment, the inner linear arrays 601a, 611a tend to push the linear arrays 690a, 690b outward. Again, since these forces are in opposition to each other, the door 45 remains aligned. As was described above, it is also possible to have multiple sets of linear arrays on the door 45, and two linear arrays on the wall 20, if desired. This configuration of magnets also provides a separation mechanism and an alignment mechanism.

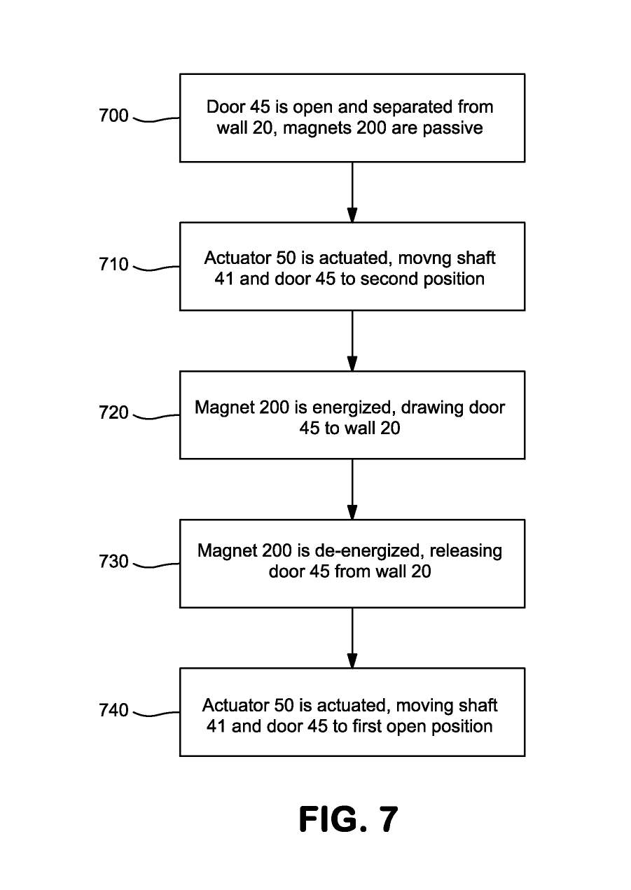

The process by which the slitvalve 10 is used to close the opening, thereby isolating the environments on the opposing sides of the wall 20 from each other, will be described and is shown in FIG. 7. It is assumed that the door 45 is open, which means that the actuator 50 is in its first open position, and the electrically switchable magnets 200 are in their non-magnetic, or passive, state, as shown in step 700 of FIG. 7. The actuator 50 is then actuated and causes the shaft 41, and consequently the door 45, to move to a second position, as shown in step 710. This may be achieved through the application of CDA or other methods. In embodiments containing linear arrays of magnets, the door 45 and wall 20 remain separated as the door 45 moves along the first direction 43, due to the magnetic repulsion between the linear arrays disposed in the door 45 and the linear arrays disposed in the wall 20. Once the door 45 has reached the second position, the electrically switchable magnet 200 is set to its energized state, as shown in step 720. This draws the magnetically attracted material 300 disposed on the door 45 toward the wall 20, thereby sealing the door 45 against the wall 20. The ability to move in the second direction 47 is due to the use of a mechanism 46 allowing this movement, such as flexure plates, a linear bearing or a shaft and ball slide. At this point, if electrically switchable permanent magnets were used, a loss of power will have no effect on the state of the slitvalve 10. In this closed position, the environments on opposing sides of the wall 20 are isolated from one another.

To move the door 45 to the open position, this process is simply reversed. First, the electrically switchable magnet 200 is changed to its non-energized, passive state, as shown in step 730. This removes the magnetic field and allows the magnetically attracted material 300 to be released from the electrically switchable magnet 200. The mechanism 46, such as flexure plates, returns to its non-stretched state. In addition, the linear arrays 210, 310 repel each other, which causes the door 45 to separate from the wall 20. The actuator 50 is then actuated to move the door 45 to its first open position, as shown in step 740. It is this position where workpieces may be passed through the aperture 30.

Thus, in movements that are parallel to the plane of the wall 20, such as steps 710, 740, CDA may be used to cause the motion. In steps that are normal or perpendicular to the plane of the wall 20, magnetic force is used to move the door 45.

This arrangement has many advantages. First, there is a significant reduction in the amount of CDA required to operate a load lock. In the prior art, CDA may be used to hold the door 45 against the wall, thereby consuming large amounts of CDA to generate the required force. In addition, traditional cantilevered designs require very heavy doors to help provide the necessary force to create an adequate seal. In addition, the seals currently created are uneven, since the lateral force applied by the door against the wall is not equally applied. The use of magnetic fields to seal the door to the wall allows for a much more even seal, where the pressure is spread much more evenly. The actual seals are usually made from Viton, Chemraz, and Kalrez materials. These seal profiles are typically vulcanized to the aluminum or steel door. By using magnets to create the closing force, the force can be spread out along the length of the door so that the seal force on the elastomeric seal is more consistent and the deformation of the door is minimized. This allows the use of a much lighter door, which further reduces the amount of CDA that is required.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

What is claimed is:

1. A slitvalve, comprising:
a wall defining an aperture;
an electrically switchable magnet disposed in a location of the wall; and
a movable door assembly, comprising:
a door having magnetically attracted material, disposed so as correspond to the location of the electrically switchable magnet when the door is in a closed position; and
an actuator to move the door in a first direction parallel to a plane of the wall between the closed position and an open position.

2. The slitvalve of claim 1, wherein the wall further comprises a first linear array of magnets arranged in the first direction, and wherein the door further comprises a second linear array of magnets arranged in the first direction, spatially oriented so as to correspond to the position of first linear array, such that the first linear array and second linear array repel one another.

3. The slitvalve of claim 2, wherein the first linear array of magnets and the second linear array of magnets comprise permanent magnets.

4. The slitvalve of claim 1, wherein the electrically switchable magnet comprises an electrically switchable permanent magnet.

5. The slitvalve of claim 1, further comprising a movable shaft in communication with the actuator, and a mechanism configured to enable movement in a second direction, perpendicular to the plane of the wall, the mechanism coupling the door to the shaft.

6. The slitvalve of claim 5, wherein said mechanism comprises a flexure plate.

7. The slitvalve of claim 1, wherein the wall further comprises a first linear array of magnets arranged in the first direction and a second linear array of magnets parallel to the first linear array of magnets, and wherein the door further comprises a third linear array of magnets arranged in the first direction, spatially oriented to correspond to a position between the first linear array and the second linear array, such that the first linear array and second linear array repel the third linear array.

8. The slitvalve of claim 1, wherein the wall further comprises two sets of magnets, one set of magnets on each side of the aperture, each set comprising an inner linear array arranged in the first direction, and an outer linear array of magnets parallel to the inner linear array of magnets and further from the aperture, and wherein the door further comprises two linear arrays of magnets arranged in the first direction, each spatially oriented to correspond to one of the inner linear arrays or the outer linear arrays, such that the linear arrays on the wall and the linear arrays on the door repel one another.

9. The slitvalve of claim 1, wherein the door further comprises a first linear array of magnets arranged in the first direction and a second linear array of magnets parallel to the first linear array of magnets, and wherein the wall further comprises a third linear array of magnets arranged in the first direction, spatially oriented to correspond to a position between the first linear array and the second linear array, such that the first linear array and second linear array repel said third linear array.

10. The slitvalve of claim 1, wherein the door further comprises two sets of magnets, each set comprising an inner linear array arranged in the first direction, and an outer linear array of magnets parallel to the inner linear array of magnets and closer to an edge of the door, and wherein the wall further comprises two linear arrays of magnets arranged on either side of the aperture and in the first direction, each spatially oriented to correspond to one of the inner linear arrays or the outer linear array, such that the linear arrays on the wall and the linear arrays on the door repel one another.

11. A method of passing a workpiece from a first environment to a second environment, separated from the first environment by a wall having an aperture therethrough, where the aperture is sealed using a movable door, the method comprising:
providing a magnetically attracted material on the door;
deactivating an electrically switchable magnet disposed in the wall, thereby releasing the magnetically attracted material from the wall;
using a force to maintain separation between the wall and the door;
using an actuator to move the door from a second position to a first position;
passing the workpiece through the aperture when the door is in the first position;
using the actuator to move the door to the second position; and
activating the electrically switchable magnet to attract the magnetically attracted material in the door, thereby sealing the door to the wall.

12. The method of claim 11, wherein the force to maintain separation is provided by additional magnets disposed on the wall and on the door.

13. The method of claim 11, wherein the actuator is coupled to the door using a shaft, and the door is attached to the shaft using a flexure plate.

14. A slitvalve, comprising:
a wall defining an aperture;
a door;
a first actuator to move the door in a first direction, parallel to a plane of the wall; and
an electrically switchable magnet to move the door in a second direction, normal to the plane of the wall.

15. The slitvalve of claim 14, wherein the first actuator comprises a pneumatic or air cylinder.

16. The slitvalve of claim 14, wherein the electrically switchable magnet is disposed on the wall.

17. The slitvalve of claim 16, wherein a magnetically attracted material is disposed on the door in a position corresponding to the electrically switchable magnet when the door is in a closed position.

18. The slitvalve of claim 14, wherein the electrically switchable magnet is disposed on the door.

19. The slitvalve of claim 18, wherein a magnetically attracted material is disposed on the wall in a position corresponding to the electrically switchable magnet when the door is in a closed position.
